(19) United States
(12) Patent Application Publication
(10) Pub. No.: US 2010/0193000 A1
(43) Pub. Date: Aug. 5, 2010

(54) THERMOELECTRIC GENERATOR FOR CONVERTING THERMAL ENERGY INTO ELECTRICAL ENERGY

(76) Inventors: Peter Prenninger, Graz (AT); Peter F. Rogl, Wien (AT); Andriy Grytsiv, Leobersdorf (AT)

Correspondence Address: DYKEMA GOSSETT PLLC, FRANKLIN SQUARE, THIRD FLOOR WEST, 1300 I STREET, NW, WASHINGTON, DC, 20005, US

(21) Appl. No.: 12/452,121

(22) PCT Filed: Jun. 20, 2008
(86) PCT No.: PCT/EP2008/057849

§ 371 Date: Jan. 4, 2010

(30) Foreign Application Priority Data
Jun. 21, 2007 (AT) A 968/2007

(51) Int. Cl. H01L 35/28

(52) U.S. Cl. 136/203

(57) ABSTRACT

A thermoelectric generator for converting thermal energy into electrical energy includes a plurality of Peltier elements which are coupled into a module and are arranged between a heat source and a heat sink, with each Peltier element having of a p-doped leg and an n-doped leg which are connected at their ends in an electrically conductive manner by electrodes. Both the p-doped legs and the n-doped legs of the individual Peltier elements are made of different materials, the efficiency of which is optimized with respect to the different temperature values at the contact points of the individual Peltier elements to the heat source. The high-temperature range of the p-doped legs includes MM_{y}Fe₄₋ₓCoₓSb₁₂ and/or MM_{y}Fe₄₋ₓNiₓSb₁₂, with MM being a misch metal of La, Ce, Pr, Nd and Sm, and the high-temperature range of the n-doped legs includes A_{y}Co₄₋ₓTₓSb₁₂, with A standing for Ba, Ca, Sr and a mixture thereof and T for Ni and Pd.

The invention relates to a thermoelectric generator for converting thermal energy into electrical energy, comprising a plurality of Peltier elements which are coupled into a module and are arranged between a heat source and a heat sink, with each Peltier element consisting of a p-doped leg and an n-doped leg which are connected at their ends in an electrically conductive manner by electrodes.

The utilization of waste heat by means of thermoelectric generators TEG or by means of Peltier elements is known from several applications. The Peltier element is used for direct conversion of heat into electrical energy. An n-type semiconductor and a p-type semiconductor are paired and the charge carriers are displaced by an outer temperature gradient, through which current can flow in the outer circuit.

A method and a device for generating electrical energy from thermal energy according to the Seebeck effect is known for example from DE 199 46 806 A1, with a Peltier module consisting of a plurality of Peltier elements being arranged in thermally conductive contact with a heat-absorbing and a heat-emitting module conduction body and are subjected to a temperature gradient via the legs of the Peltier elements. The resulting voltage is increased accordingly by switching the Peltier elements behind one another and is used for generation of electricity. An exemplary application is mentioned to be the utilization of the waste heat in an engine block or the exhaust system of an internal combustion engine.

It is further known from U.S. Pat. No. 4,095,998 A to arrange several rows of thermoelectric generators consisting of p-type and n-type elements in the shape of a star along an exhaust gas system which is flowed through by a stream of exhaust gases and to thus reclaim thermoelectric energy. The individual p-type and n-type elements are arranged similarly.

DE 10 2004 005 151 A1 describes a sensor device and a system for measuring the state of a medium, with a thermoelectric generator being used as an energy source of an oil condition sensor, which generator obtains its energy with the help of a Peltier element from the temperature difference between the medium to be measured (e.g. oil) and the ambient environment.

In many of the mentioned applications, the employed thermoelectric generators have an only very low efficiency of approx. 5%. It is the object of the invention to significantly increase this efficiency, especially also in cases where the heat source shows a locally inhomogeneous temperature distribution.

This object is achieved in accordance with the invention in such a way that both the p-doped legs (Sp1, Sp2, Sp3 . . . ) and the n-doped legs (Sn1, Sn2, Sn3 . . . ) of the individual Peltier elements (E1, E2, E3 . . . ) consist of different materials (P1, P2, P3 . . . , N1, N2, N3 . . . ) depending on the different temperature values (T₁, T₂, T₃ . . . ) at the contact points of the individual Peltier elements (E1, E2, E3 . . . ) to the heat source (Q). The p-doped and n-doped legs of the individual Peltier elements of the generator in accordance with the invention, which Peltier elements are coupled into modules, are not arranged similarly, but are made of different materials within the terms of an optimization of the efficiency in the conversion of thermal energy into electrical energy.

The invention will be explained below in closer detail by reference to schematic drawings, wherein:

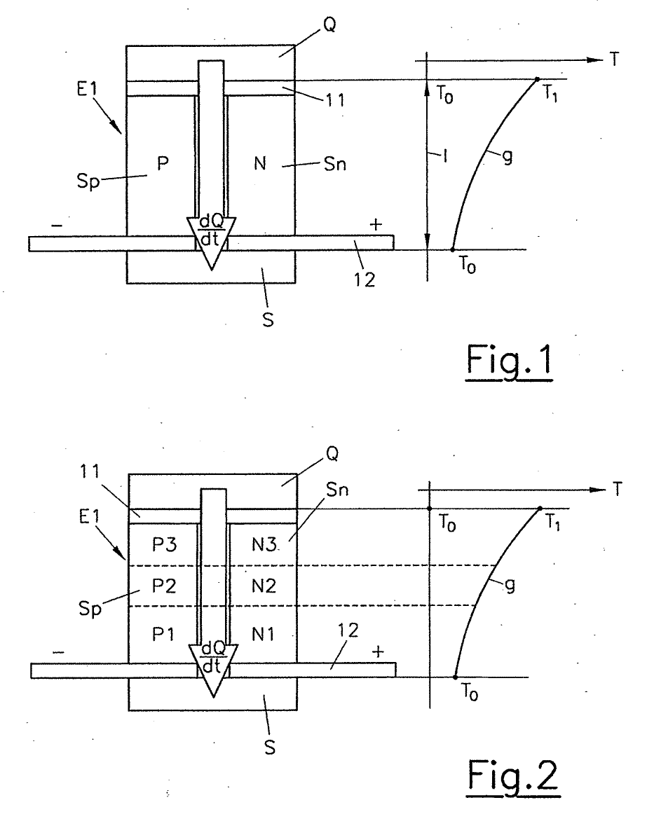

FIG. 1 shows a Peltier element according to the state of the art;

FIG. 2 shows an advantageous variant of a Peltier element according to the state of the art;

FIG. 3 shows a thermoelectric generator in accordance with the invention for converting thermal energy into electrical energy;

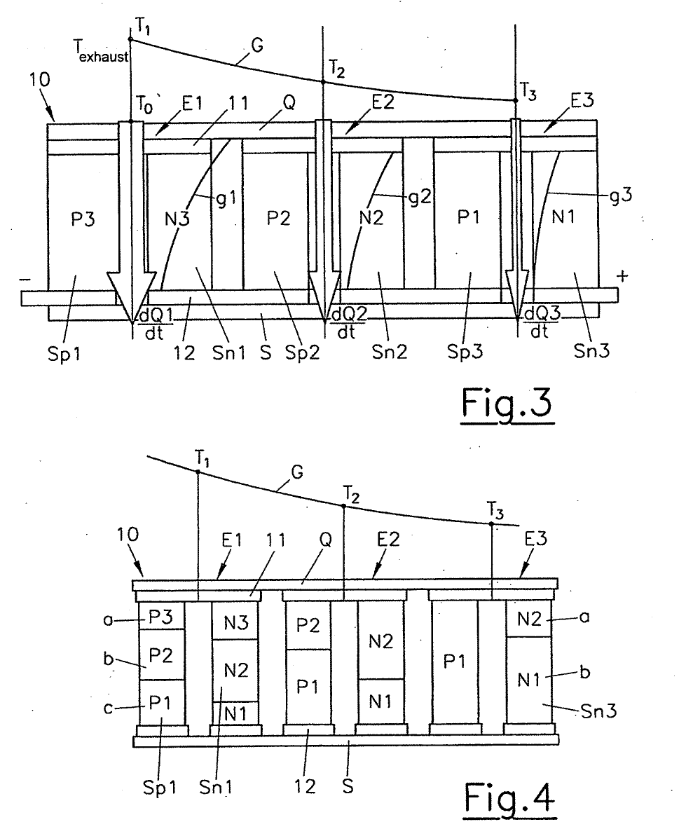

FIG. 4 shows a preferred variant of a thermoelectric generator in accordance with the invention;

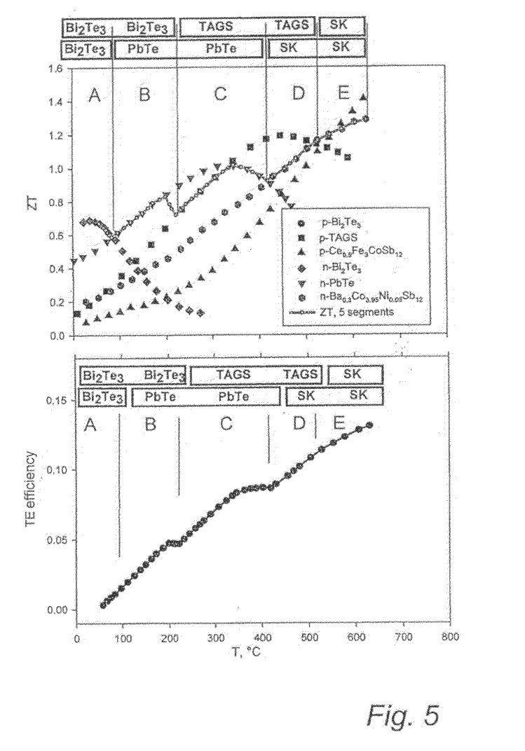

FIG. 5 shows a diagram on the thermoelectric efficiency of a segmented Peltier element in a temperature range of between 0° C. and 600° C., and

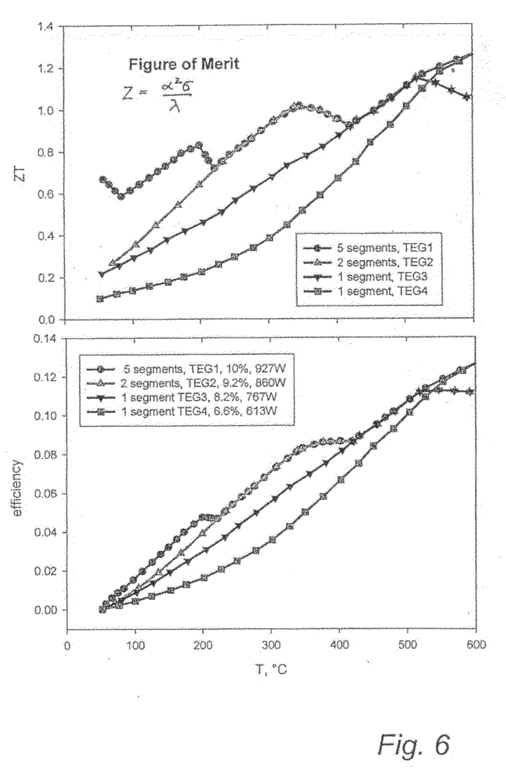

FIG. 6 shows a comparison of the efficiencies of differently structured Peltier elements in a temperature range of between 0° C. and 600° C.

Reference is hereby made to FIGS. 1 and 2 for better understanding of the invention, which show illustrations according to the state of the art. FIG. 1 shows a Peltier element E1 which consists of a p-doped leg Sp and an n-doped leg Sn which are connected with each other in a conductive manner with the help of electrodes 11 and 12. The heat gradient g as shown in the right section of the illustration is formed between the heat source Q with temperature T₁ and the heat sink S with temperature T₀. The heat flow dQ/dt from the heat source Q to the heat sink S is shown further with an arrow. In the simplest of cases, materials P and N are used for the leg Sp and the leg Sn which have the best possible efficiency for the expected temperature range T₀ to T₁.

FIG. 2 represents an improvement of a Peltier element according to FIG. 1, in which both the p-doped leg Sp as well as the n-doped leg Sn are subdivided into several sections with different materials P1 to P3 and N1 to N3, so that materials can be used in this case which are each adjusted optimally to the respective gradient curve g.

According to FIG. 3, the invention now goes beyond this known state of the art and considers the fact that the heat source Q can have different temperature values T₁, T₂, T₃ . . . at the contact points of the individual Peltier elements E1, E2, E3 . . . , so that both the p-doped legs Sp1, Sp2, Sp3 . . . and the n-doped legs Sn1, Sn2, Sn3 . . . of the individual Peltier elements E1, E2, E3 . . . have different materials P1, P2, P3 . . . , N1, N2, N3 . . . , the efficiency of which is optimized with respect to the different temperature values (T₁, T₂, T₃ . . . ). Each Peltier element of module 10 can be arranged differently and be adjusted optimally to the locally prevailing temperature difference between the heat source Q and the heat sink S. For example, planar modules 10 are possible which utilize optimally the waste heat of an engine block or an oil sump because different semiconductor materials can be used in the Peltier elements E1, E2, E3 . . . at contact points of different temperature of the heat source. They can be chosen in a purposeful manner on the basis of efficiency diagrams of the individual semiconductor materials.

The individual Peltier elements E1, E2, E3 . . . can also be arranged along a heat source Q which extends in a substantially linear fashion and which comprises a temperature gradient G which drops continually from an output temperature T1 to a final temperature T3 for example. It is therefore necessary to thus consider the individual temperature gradients g1, g2, g3 . . . within the individual Peltier elements E1, E2, E3 . . . and the temperature gradient G along the heat source Q.

In a concrete example, the individual Peltier elements E1, E2, E3 . . . can be arranged along an exhaust gas system of an internal combustion engine which is flowed through by hot exhaust gas, with the heat source Q being formed by the surface of the exhaust gas system and the heat sink S having the temperature Tₒ of the ambient temperature. The starting temperature T₁ lies close to approx. 600° C., the final T₃ close to approx. 70° C.

In the embodiment according to FIG. 4, both the p-doped legs Sp1, Sp2, Sp3 . . . and the n-doped legs Sn1, Sn2, Sn3 . . . have individual sections a, b, c and consist of different materials P1, P2, P3 . . . , N1, N2, N3 . . . with respect to the different temperature gradient (g1, g2, g3) obtained between the temperature values T₁, T₂, T₃ . . . of the contact points to the heat source Q and the temperature value T₀ of the heat sink S.

A further optimization can occur in accordance with the invention in such a way that the individual sections a, b, c of the p-doped legs Sp1, Sp2, Sp3 . . . and the n-doped legs Sn1, Sn2, Sn3 . . . have different lengths depending on the respectively present temperature gradients g1, g2, g3 . . . .

FIG. 5 shows an example in the form of the thermoelectric efficiency of a segmented Peltier element in a temperature range of between 0° C. and 600° C. The p-doped leg, like the n-doped leg, consists of three sections of different length, so that as a result of overlapping of individual sections as shown in FIG. 5 five combinations of material are obtained in the temperature ranges A to E in which the following semiconductor materials are present for example in both legs (the designation TAGS stands for (GeTe)₁₋ₓ(AgSbTe)ₓ, with x=0.1 to 0.15 applying):

TABLE 1

| | Temp. range | | |
|---|---|---|---|
| Combination | (° C.) | p-doped leg | n-doped leg |
| A | 0-100 | (Bi, Sb)₂Te₃ | Bi₂Te₃ |
| B | 100-200 | (Bi, Sb)₂Te₃ | PbTe |
| C | 200-450 | TAGS | PbTe |
| D | 450-550 | TAGS | Ba_{0.3}Co_{3.95}Ni_{0.05}Sb₁₂ |
| E | >550 | Ce_{0.9}Fe₃CoSb₁₂ | Ba_{0.3}Co_{3.95}Ni_{0.05}Sb₁₂ |

Other suitable p-doped or n-doped Skutterudites can also be used instead of Ce_{0.9}Fe₃CoSb₁₂ or Ba_{0.3}Co_{3.95}Ni_{0.05}Sb₁₂ in Tab. 1.

FIG. 6 compares the efficiency of differently structured Peltier elements TEG1 to TEG4 in the temperature range of between 0° C. and 600° C. with each other, with the following combinations of materials from Tab. 1 being used for TEG1 to TEG4:

TABLE 2

| | Combination | Efficiency (%) | Electric power (W) |
|---|---|---|---|
| TEG1 | ABCDE | 10 | 927 |
| TEG2 | CD | 9.2 | 860e |
| TEG3 | D | 8.2 | 767 |
| TEG4 | E | 6.6 | 613 |

Suitable combinations of materials for defined temperature ranges can be chosen on the basis of such tables.

According to an advantageous variant of the invention, at least the high-temperature range of the p-doped legs comprises Fe-based Skutterudites (SK), e.g. Ce_{0.9}Fe₃CoSb₁₂, Yb_{0.75}Fe_{3.5}Ni_{0.5}Sb₁₂, MM_{y}Fe₄₋ₓCoₓSb₁₂ and/or MM_{y}Fe₄₋ₓNiₓSb₁₂, with MM being a misch metal of La, Ce, Pr, Nd and Sm ist. Furthermore, at least the high-temperature range of the n-doped legs comprises Co-based Skutterudites (SK), e.g. Yb_{y}Co₄₋ₓPtₓSb₁₂, Ba_{0.3}Co_{3.95}Ni_{0.05}Sb₁₂ and/or A_{y}Co₄₋ₓTₓSb₁₂, with A standing for Ba, Ca, Sr and a mixture thereof and T for Ni and Pd.

Within the terms of cost reduction, the relatively expensive Co can be replaced entirely or partly by Ni, and Ce by a misch metal of La, Ce, Pr, Nd and Sm, based on Ce_{0.9}Fe₃CoSb₁₂. It is further possible to replace the Yb in Yb_{0.75}Fe_{3.5}Ni_{0.5}Sb₁₂ entirely or partly by Ce, and to substitute certain percentages of Co or Pt in Yb_{y}Co₄₋ₓPtₓSb₁₂ or Ba_{0.3}Co_{3.95}Ni_{0.05}Sb₁₂ by the substantially cheaper Ni.

In order to increase the efficiency of the thermoelectric elements, the previously mentioned starting material Ce can be replaced by a misch metal (La, Ce, Pr, Nd and Sm), or the pure Ba by a mixture of Ba, Ca, Sr.

As a result, the following combinations of materials (P3, N3) are obtained for example for the high-temperature range p-doped legs (Sp1, Sp2, Sp3 . . . ) and the n-doped legs (Sn1, Sn2, Sn3 . . . ), with the heat source lying in the range of 600° C.:

TABLE 3

| p-doped leg | n-doped leg |
|---|---|
| MM_{0.75}Fe_{3.5}Ni_{0.5}Sb₁₂ | Ba_{0.3}Co₄Sb₁₂ |
| MM_{0.75}Fe_{3.0}Co_{1.0}Sb₁₂ | Ba_{0.3}Co_{3.95}Ni_{0.05}Sb₁₂ |
| Pr_{0.75}Fe_{3.5}Ni_{0.5}Sb₁₂ | Ca_{0.1}Ba_{0.1}Sr_{0.1}Co₄Sb₁₂ |
| Pr_{0.75}Fe_{3.0}Co_{1.0}Sb₁₂ | Ca_{0.1}Ba_{0.1}Sr_{0.1}Co_{3.95}Ni_{0.05}Sb₁₂ |
| Ce_{0.75}Fe₃CoSb₁₂ | |
| Ce_{0.90}Fe₃CoSb₁₂ | |

1-10. (canceled)

11. A thermoelectric generator for converting thermal energy into electrical energy, comprising a plurality of Peltier elements which are coupled into a module and are arranged between a heat source and a heat sink, with each Peltier element consisting of a p-doped leg and an n-doped leg which are connected at their ends in an electrically conductive manner by electrodes,
wherein both the p-doped legs and the n-doped legs of the individual Peltier elements consist of different materials depending on different temperature values at the contact points of the individual Peltier elements to the heat source,
wherein the high-temperature range of the p-doped legs is based on Fe-based Skutterudites, e.g., Ce_{0.9}Fe₃CoSb₁₂, Yb_{0.75}Fe_{3.5}Ni_{0.5}Sb₁₂, comprising MM_{y}Fe₄₋ₓCoₓSb₁₂ and/or MM_{y}Fe₄₋ₓNiₓSb₁₂, with MM being a misch metal of La, Ce, Pr, Nd and Sm, and
wherein the high-temperature range of the n-doped legs is based on Co-based Skutterudites, e.g., Yb_{y}Co₄₋ₓPtₓSb₁₂, comprising A_{y}Co₄₋ₓTₓSb₁₂, with A standing for Ba, Ca, Sr and a mixture thereof and T for Ni and Pd.

12. The thermoelectric generator according to claim 11, wherein both the p-doped legs and the n-doped legs have individual sections and consist of different materials with respect to the different temperature gradient obtained between the temperature values of the contact points to the heat source and the temperature value of the heat sink.

13. The thermoelectric generator according to claim 12, wherein the individual sections of the p-doped legs and the n-doped legs have different lengths depending on the respectively present temperature gradients.

14. The thermoelectric generator according to claim 11, wherein the individual Peltier elements are arranged along a substantially linearly extending heat source which has a temperature gradient.

15. The thermoelectric generator according to claim 14, wherein the individual Peltier elements are arranged along an exhaust gas system which is flowed through by an exhaust gas, so that the heat source is formed by the surface of the exhaust heat system and the heat sink has the temperature of the ambient temperature.

16. The thermoelectric generator according to claim 11, wherein the p-doped legs and the n-doped legs have the following combinations of materials in the high-temperature range:

| p-doped leg | n-doped leg |
|---|---|
| MM_{0.75}Fe_{3.5}Ni_{0.5}Sb₁₂ | Ba_{0.3}Co₄Sb₁₂ |
| MM_{0.75}Fe_{3.0}Co_{1.0}Sb₁₂ | Ba_{0.3}Co_{3.95}Ni_{0.05}Sb₁₂ |
| | Ca_{0.1}Ba_{0.1}Sr_{0.1}Co₄Sb₁₂ |
| | Ca_{0.1}Ba_{0.1}Sr_{0.1}Co_{3.95}Ni_{0.05}Sb₁₂ |

17. A thermoelectric generator for converting thermal energy into electrical energy, comprising at least one Peltier element which is arranged between a heat source in the range of 600° C. and a heat sink, with the Peltier element consisting of a p-doped leg and an n-doped leg which are connected in an electrically conductive manner at their ends by electrodes, wherein the high-temperature range of the p-doped legs is based on Fe-based Skutterudites, e.g., Ce_{0.9}Fe₃CoSb₁₂, Yb_{0.75}Fe_{3.5}Ni_{0.5}Sb₁₂, comprising MM_{y}Fe₄₋ₓCoₓSb₁₂ and/or MM_{y}Fe₄₋ₓNiₓSb₁₂, with MM being a misch metal of La, Ce, Pr, Nd and Sm, and wherein the high-temperature range of the n-doped legs is based on Co-based Skutterudites, e.g., Yb_{y}Co₄₋ₓPtₓSb₁₂, comprising A_{y}Co₄₋ₓTₓSb₁₂, with A standing for Ba, Ca, Sr and a mixture thereof and T for Ni and Pd.

18. The thermoelectric generator according to claim 17, wherein the p-doped legs and the n-doped legs have the following combinations of materials in the high-temperature range:

| p-doped leg | n-doped leg |
|---|---|
| MM_{0.75}Fe_{3.5}Ni_{0.5}Sb₁₂ | Ba_{0.3}Co₄Sb₁₂ |
| MM_{0.75}Fe_{3.0}Co_{1.0}Sb₁₂ | Ba_{0.3}Co_{3.95}Ni_{0.05}Sb₁₂ |
| | Ca_{0.1}Ba_{0.1}Sr_{0.1}Co₄Sb₁₂ |
| | Ca_{0.1}Ba_{0.1}Sr_{0.1}Co_{3.95}Ni_{0.05}Sb₁₂ |
